(19) United States
(12) Patent Application Publication
(10) Pub. No.: US 2022/0124933 A1
(43) Pub. Date: Apr. 21, 2022

(54) SERVER CHASSIS

(71) Applicant: HONGFUJIN PRECISION ELECTRONICS(TIANJIN)CO.,LTD., Tianjin (CN)

(72) Inventors: HAN-YU LI, New Taipei (TW); WEN-HU LU, Tianjin (CN); CHEN XING, Tianjin (CN); SHU-YING CEN, Tianjin (CN)

(21) Appl. No.: 17/121,608

(22) Filed: Dec. 14, 2020

(30) Foreign Application Priority Data
Oct. 20, 2020 (CN) 202011126186.7

(51) Int. Cl. H05K 7/14; H05K 7/18

(52) U.S. Cl. CPC H05K 7/1489; H05K 7/183

(57) ABSTRACT

A server chassis includes a housing provided with a receiving cavity and an opening. A number of trays is arranged in the receiving cavity in a stacked manner. Two sides of each tray are slidably coupled to the housing. Each of the trays is configured to slide out or retract into the receiving cavity through the opening. Each of the trays is used for carrying hard disks in multiple arrays. A difference between a height of the housing and a total height of the trays is less than a height of one tray.

### FIELD

The subject matter herein generally relates to servers, and more particularly to a server chassis for a server.

### BACKGROUND

Server chassis sizes are generally measured in multiples of U, which refers to a height of the server chassis and is determined by the Electronic Industries Association (EIA). 1U=44.45 mm, and 2U=88.9 mm. The current 2U model server chassis has the problem of not being able to store hard drives in multiple layers, and performance of maintenance on the hard drives is inconvenient.

### BRIEF DESCRIPTION OF THE DRAWINGS

Implementations of the present disclosure will now be described, by way of embodiments, with reference to the attached figures.

FIG. 1 is a perspective schematic diagram of an embodiment of a server in an embodiment of the application.

FIG. 2 is a perspective schematic diagram of a tray in FIG. 1 extended out of a housing of the server chassis.

FIG. 3 is a perspective schematic diagram of the tray and a wire embedding mechanism.

### DETAILED DESCRIPTION

It will be appreciated that for simplicity and clarity of illustration, where appropriate, reference numerals have been repeated among the different figures to indicate corresponding or analogous elements. Additionally, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape, or another word that “substantially” modifies, such that the component need not be exact. For example, “substantially cylindrical” means that the object resembles a cylinder, but can have one or more deviations from a true cylinder. The term “comprising” means “including, but not necessarily limited to”; it specifically indicates open-ended inclusion or membership in a so-described combination, group, series, and the like.

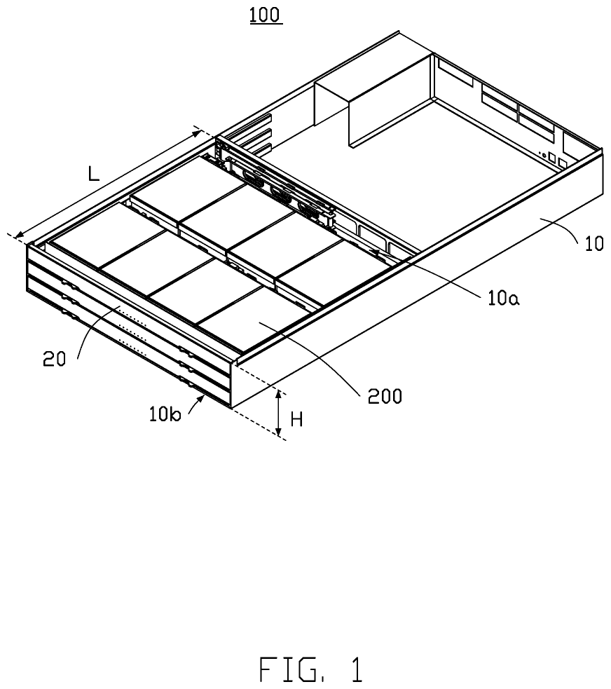

FIG. 1 shows an embodiment of a server chassis 100 capable of storing hard disks in a plurality of extendable and retractable layers. The server chassis 100 includes a housing 10 and a plurality of trays 20. The housing 10 is substantially in the shape of a rectangular parallelepiped, and an inside of the housing 10 defines a receiving cavity 10a. One end of the housing 10 is provided with an opening 10b communicating with the receiving cavity 10a. A height H of the housing 10 is 2U (88.9 mm). A plurality of trays 20 is placed in the receiving cavity 10a in a stacked manner. Each of the plurality of trays 20 is used to carry a plurality of hard disks 200. Two sides of each tray 20 are slidably coupled to side walls of the housing 10, so that the trays 20 can slide out or retract into the receiving cavity 10a through the opening 10b, so as to facilitate maintenance of the hard disks 200. A difference between the height of the housing 10 and a total height of the plurality of trays 20 is less than a height of one tray 20 to facilitate insertion of the trays 20.

Referring to FIG. 1, in one embodiment, the server chassis 100 includes three layers of trays 20 stacked on top of each other.

In one embodiment, the height H of each tray 20 is 27.3 mm.

In one embodiment, each tray 20 is used to carry 3.5-inch hard disks 200. In one embodiment, each tray 20 carries eight 3.5-inch hard disks 200, and the eight hard disks 200 are arranged in two rows and four columns.

In one embodiment, a length L of each tray 20 extending into the opening 10b is 410 mm, which can leave enough space for other components in the housing 10, such as a main board.

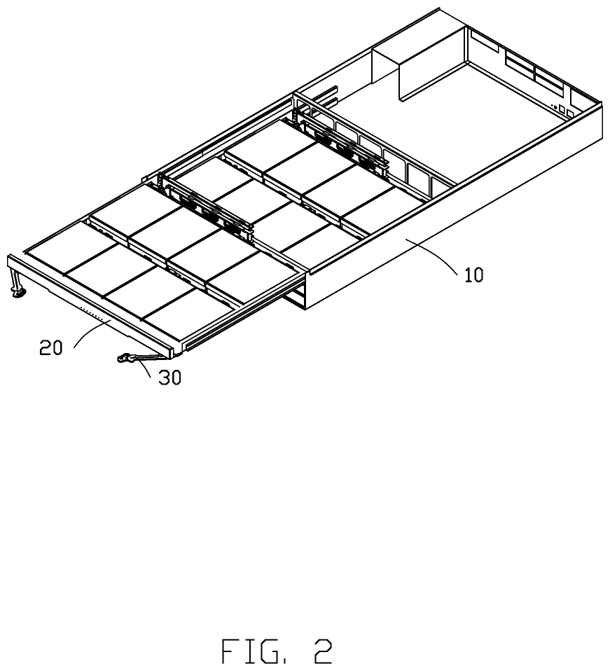

Referring to FIG. 2, in one embodiment, two handles 30 are provided at an outer end of each tray 20. The two handles 30 are respectively provided on two sides of the tray 20. One end of each handle 30 is rotationally installed at a bottom edge of the tray 20, and another end of each handle 30 can be rotated to extend or retract a bottom of the tray 20. When the handle 30 is rotated out, the tray 20 can be easily pulled out. After the tray 20 is retracted into the housing 10, the handle 30 can be rotated back to the bottom of the tray 20.

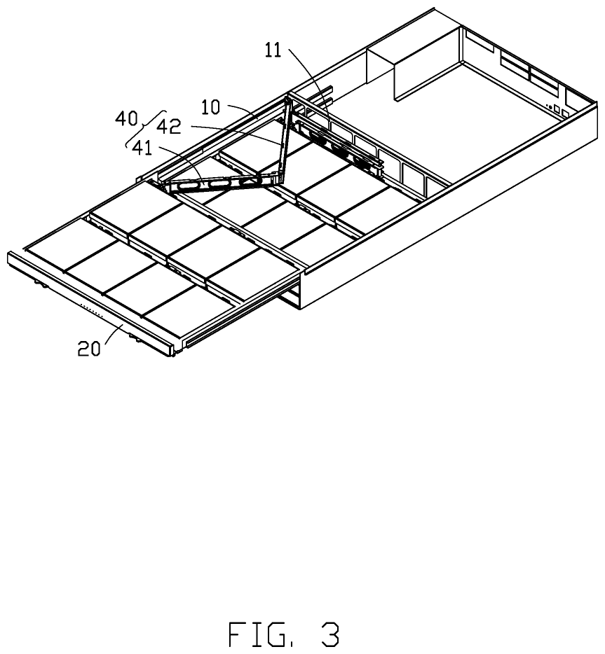

Referring to FIG. 3, in one embodiment, the server chassis 100 is provided with a wire embedding mechanism 40 for organizing cables coupled between a rear end of each tray 20 and an inside of the housing 10. The housing 10 is provided with a stop wall 11 used to limit a moving distance of the tray 20. The wire embedding mechanism 40 includes a first connecting rod 41 and a second connecting rod 42. One end of the first connecting rod 41 is rotationally coupled to an inner end of the tray 20, and another end of the first connecting rod 41 is rotationally coupled to the second connecting rod 42 with a restricted angle. An end of the second connecting rod 42 away from the first connecting rod 41 is rotationally coupled to the stop wall 11. The first connecting rod 41 and the second connecting rod 42 are elongated rectangular-shaped. When the tray 20 is retracted into the housing 10, the first connecting rod 41 and the second connecting rod 42 are folded between the tray 20 and the stop wall 11. When the tray 20 extends out of the housing 10, the first connecting rod 41 and the second connecting rod 42 are unfolded. The cables are arranged along the first connecting rod 41 and the second connecting rod 42 and can be unfolded or folded along with the first connecting rod 41 and the second connecting rod 42. The first connecting rod 41 and the second connecting rod 42 are used to prevent the cables from being entangled with each other.

Specifically, a total length of the first connecting rod 41 and the second connecting rod 42 is greater than the distance L that the tray 20 moves through the opening 10b, so as to prevent the first connecting rod 41 and the second connecting rod 42 from being straight when the tray 20 is pulled out. Thus, the tray 20 is prevented from being stuck in position and unable to be retracted as a result of the first connecting rod 41 and the second connecting rod 42 being straight.

In one embodiment, there are three sliding grooves (not shown) on inner side walls of the housing 10, and inserting strips (not shown) are arranged on sides of each tray 20, and the inserting strips are slidably inserted into the corresponding sliding grooves, so that the tray 20 can slide in the housing 10.

It is understandable that, in other embodiments, each tray 20 can carry other numbers of hard disks, and the trays 20 can carry other electronic components.

An embodiment of the present application also provides a server (not shown) including the server chassis 100 described above.

The above-mentioned server chassis 100 and the server are placed in a 2U-height housing 10 through a plurality of stacked trays 20, and each tray 20 can slide out or retract through the opening 10b, so that the server chassis 100 is capable of storing the hard disks 200 in a plurality of extendable and retractable layers in a 2U model. Furthermore, the number of hard disks 200 that can be stored is increased, and maintenance of the hard disks 200 is facilitated.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

1. A server chassis comprising:
a housing provided with a receiving cavity and an opening, a height of the housing being 2U;
a plurality of trays arranged in the receiving cavity in a stacked manner, two sides of each of the plurality of trays slidably coupled to the housing, each of the plurality of trays configured to slide out or retract into the receiving cavity through the opening, and each of the plurality of trays used for carrying hard disks in multiple arrays; wherein:
a difference between a height of the housing and a total height of the plurality of trays is less than a height of one tray;
wherein two handles are respectively provided on two sides of each of the plurality of trays, one end of each of the two handles is rotationally installed at a bottom edge of a corresponding one tray, and another end of each of the two handles is rotated to extend or retract the bottom edge of the corresponding one tray.

2. The server chassis of claim 1, wherein:
the plurality of trays is arranged in three layers.

3. The server chassis of claim 2, wherein:
a height of each tray is 27.3 mm.

4. The server chassis of claim 3, wherein:
each tray is used to carry 3.5-inch hard disks.

5. The server chassis of claim 4, wherein:
each tray carries eight 3.5-inch hard disks, and the hard disks are arranged in a 2×4 array.

6. The server chassis of claim 5, wherein:
a maximum distance that the tray extends through the opening is 410 mm.

7. The server chassis of claim 1, wherein:
at least one handle is provided at an outer end of each tray.

8. The server chassis of claim 1, wherein:
a rear end of each tray is provided with a wire embedding mechanism for arranging cables coupled between the rear end of the tray and an inside of the housing.

9. The server chassis of claim 8, wherein:
the wire embedding mechanism comprises a first connecting rod and a second connecting rod;
one end of the first connecting rod is rotationally coupled to one end of the second connecting rod;
another end of the first connecting rod is coupled to the rear end of the tray; and
another end of the second connecting rod is coupled to the housing.

10. A server chassis comprising:
a housing provided with a receiving cavity and an opening, the opening communicating with the receiving cavity;
a plurality of trays arranged in the receiving cavity in a stacked manner, two sides of each of the plurality of trays slidably coupled to the housing, each of the plurality of trays configured to slide out or retract into the receiving cavity through the opening, and each of the plurality of trays used for carrying a plurality of hard disks; and
a plurality of wire embedding mechanisms respectively corresponding to each of the plurality of trays, one end of the wire embedding mechanism coupled to a rear end of the respective tray, and another end of the wire embedding mechanism coupled to the housing, the wire embedding mechanism configured to fold when the tray is retracted into the housing and unfold when the tray is extended out of the housing; wherein:
a difference between a height of the housing and a total height of the plurality of trays is less than a height of one tray; and
a total length of the wire embedding mechanism is greater than a distance that the tray moves through the opening;
wherein two handles are respectively provided on two sides of each of the plurality of trays, one end of each of the two handles is rotationally installed at a bottom edge of a corresponding one tray, and another end of each of the two handles is rotated to extend or retract the bottom edge of the corresponding one tray.

11. The server chassis of claim 10, wherein:
the plurality of trays is arranged in three layers.

12. The server chassis of claim 11, wherein:
a height of each tray is 27.3 mm.

13. The server chassis of claim 12, wherein:
each tray is used to carry 3.5-inch hard disks.

14. The server chassis of claim 13, wherein:
each tray carries eight 3.5-inch hard disks, and the hard disks are arranged in a 2×4 array.

15. The server chassis of claim 14, wherein:
a maximum distance that the tray extends through the opening is 410 mm.

16. The server chassis of claim 15, wherein:
at least one handle is provided at an outer end of each tray.

17. The server chassis of claim 16, wherein:
a rear end of each tray is provided with a wire embedding mechanism for arranging cables coupled between the rear end of the tray and an inside of the housing.

18. The server chassis of claim 17, wherein:
the wire embedding mechanism comprises a first connecting rod and a second connecting rod;
one end of the first connecting rod is rotationally coupled to one end of the second connecting rod;
another end of the first connecting rod is coupled to the rear end of the tray; and
another end of the second connecting rod is coupled to the housing.
